(19) United States
(12) Patent Application Publication
(10) Pub. No.: US 2024/0006559 A1
(43) Pub. Date: Jan. 4, 2024

(54) DISPLAY DEVICE

(71) Applicant: Samsung Display Co., LTD., Yongin-si (KR)

(72) Inventors: Je Won YOO, Yongin-si (KR); Min Joo KIM, Yongin-si (KR); Hoon KIM, Yongin-si (KR); Seung Kyu LEE, Yongin-si (KR); Yong Sik HWANG, Yongin-si (KR)

(21) Appl. No.: 18/314,608

(22) Filed: May 9, 2023

(30) Foreign Application Priority Data
Jul. 4, 2022 (KR) 10-2022-0081907

(51) Int. Cl. H01L 33/38; H01L 25/075; H01L 33/44

(52) U.S. Cl. CPC H01L 33/382; H01L 25/0753; H01L 33/44

(57) ABSTRACT

A display device is provided. The display device comprises a substrate, a first electrode and a second electrode above the substrate, extending in one direction, and spaced apart from each other in another direction, a light-emitting element above the first electrode and the second electrode, a first connection electrode contacting one end portion of the light-emitting element, a second connection electrode contacting another end portion of the light-emitting element, and a first insulating layer between the light-emitting element and the first and second electrodes, and including a light-blocking material.

### CROSS-REFERENCE TO RELATED APPLICATION

This application claims priority to, and the benefit of, Korean Patent Application No. 10-2022-0081907 filed on Jul. 4, 2022 in the Korean Intellectual Property Office, the contents of which in its entirety are herein incorporated by reference.

### BACKGROUND

### 1. Field

The present disclosure relates to a display device.

### 2. Description of the Related Art

The importance of display devices has steadily increased with the development of multimedia technology. In response thereto, various types of display devices, such as an organic light-emitting display (OLED), a liquid crystal display (LCD) and the like have been used.

As a device for displaying an image of a display device, there is a self-light-emitting display device including a light-emitting element. The self-light-emitting display device includes an organic light-emitting display device using an organic material as a light-emitting material for a light-emitting element, an inorganic light-emitting display device using an inorganic material as a light-emitting material, or the like.

### SUMMARY

Aspects of the present disclosure provide a display device capable of reducing reflectance.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, a display device includes a substrate, a first electrode and a second electrode above the substrate, extending in one direction, and spaced apart from each other in another direction, a light-emitting element above the first electrode and the second electrode, a first connection electrode contacting one end portion of the light-emitting element, a second connection electrode contacting another end portion of the light-emitting element, and a first insulating layer between the light-emitting element and the first and second electrodes, and including a light-blocking material.

The first insulating layer may contact top surfaces of the first electrode and the second electrode, and may contact a bottom surface of the light-emitting element.

The light-blocking material may include a black pigment including carbon black.

The first insulating layer may include an organic material with the light-blocking material scattered therein.

The display device may further include a bank layer above the first insulating layer, and separating an emission area from a subsidiary area.

The first insulating layer may overlap an entirety of the first electrode and the second electrode in the emission area.

The display device may further include a first bank pattern above the substrate and the first electrode, and a second bank pattern above the substrate and the second electrode, wherein the first insulating layer overlaps the first bank pattern and the second bank pattern.

The display device may further include a second insulating layer between the light-emitting element and the first insulating layer, wherein the second insulating layer does not include the light-blocking material.

The second insulating layer may be in contact with a bottom surface of the light-emitting element and a top surface of the first insulating layer.

The second insulating layer may entirely overlap the first insulating layer. The display device may further include a light-transmissive layer above the first connection electrode and the second connection electrode, and configured to transmit light emitted from the light-emitting element, an overcoat layer above the light-transmissive layer, and a polarizing plate above the overcoat layer.

The light-emitting element may include a first semiconductor layer including a p-type dopant, a second semiconductor layer above the first semiconductor layer and including an n-type dopant, and an emissive layer between the first insulating layer and the second insulating layer.

According to an aspect of the present disclosure, a display device includes a substrate, a first electrode and a second electrode above the substrate, extending in one direction, and spaced apart from each other another direction, a first insulating layer above the first electrode and the second electrode, light-emitting elements above the first insulating layer, and between the first electrode and the second electrode, a first connection electrode contacting one end portions of the light-emitting elements, and overlapping the first electrode, a second connection electrode contacting other end portions of the light-emitting element, and overlapping the second electrode, and a light-blocking layer above the first insulating layer, the first connection electrode, and the second connection electrode.

The light-blocking layer may include an organic material and a light-blocking material scattered therein.

The light-emitting elements might not overlap the first electrode and the second electrode.

A gap between the first electrode and the second electrode may be greater than a length of the light-emitting elements.

The display device may further include a bank layer between the first insulating layer and the light-blocking layer, and separating an emission area from a subsidiary area.

The light-blocking layer may define a first opening exposing one or more of the light-emitting elements in the emission area.

The light-blocking layer might not overlap the light-emitting elements.

The light-emitting elements may emit any one of light of a first color, light of a second color, and light of a third color, wherein the first color is red, the second color is green, and the third color is blue.

In accordance with the display device according to the present disclosure, by including a first insulating layer including a light-blocking material, electrodes having high reflectance are covered to reduce or prevent reflection of external light. Accordingly, the reflectance of the display device is reduced to improve display quality.

However, the aspects of the present disclosure are not limited to the aforementioned aspects, and various other aspects are included in the present specification.

### BRIEF DESCRIPTION OF THE DRAWINGS

The above and other aspects of the present disclosure will become more apparent by describing in detail embodiments thereof with reference to the attached drawings, in which:

FIG. 1 is a schematic plan view of a display device according to one or more embodiments;

FIG. 2 is a schematic layout view illustrating a plurality of wires of a display device according to one or more embodiments;

FIG. 3 is a plan view showing a pixel of a display device according to one or more embodiments of the present disclosure;

FIG. 4 is a cross-sectional view taken along the line E1-E1′ of FIG. 3;

FIG. 5 is a cross-sectional view taken along the line E2-E2′ of FIG. 3;

FIG. 6 is a schematic view of a light-emitting element according to one or more embodiments;

FIG. 7 is a cross-sectional view of a display device according to one or more other embodiments;

FIG. 8 is a cross-sectional view of a display device according to still yet one or more other embodiments;

FIG. 9 is a plan view illustrating one pixel of a display device according to one or more embodiments;

FIG. 10 is a cross-sectional view taken along the line E3-E3′ of FIG. 9;

FIG. 11 is a view schematically illustrating electrodes and light-emitting elements according to yet one or more other embodiments;

FIG. 12 is a plan view illustrating a light-blocking layer in one sub-pixel of a display device according to yet one or more other embodiments;

FIG. 13 is a cross-sectional view of a display device according to yet one or more other embodiments; and

FIG. 14 is a cross-sectional view of a display device according to one or more embodiments.

### DETAILED DESCRIPTION

Aspects of some embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may have various modifications and may be embodied in different forms, and should not be construed as being limited to only the illustrated embodiments herein. Rather, these embodiments are provided as examples so that this disclosure will be thorough and complete, and will fully convey the aspects of the present disclosure to those skilled in the art, and it should be understood that the present disclosure covers all the modifications, equivalents, and replacements within the idea and technical scope of the present disclosure. Accordingly, processes, elements, and techniques that are not necessary to those having ordinary skill in the art for a complete understanding of the aspects of the present disclosure may not be described.

Unless otherwise noted, like reference numerals, characters, or combinations thereof denote like elements throughout the attached drawings and the written description, and thus, descriptions thereof will not be repeated. Further, parts that are not related to, or that are irrelevant to, the description of the embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the particular illustrated shapes of regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions, such as “at least one of,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, YZ, and ZZ, or any variation thereof. Similarly, the expression, such as “at least one of A and B” may include A, B, or A and B. As used herein, “or” generally means “and/or,” and the term “and/or” includes any and all combinations of one or more of the associated listed items. For example, the expression, such as “A and/or B” may include A, B, or A and B. Similarly, expressions, such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

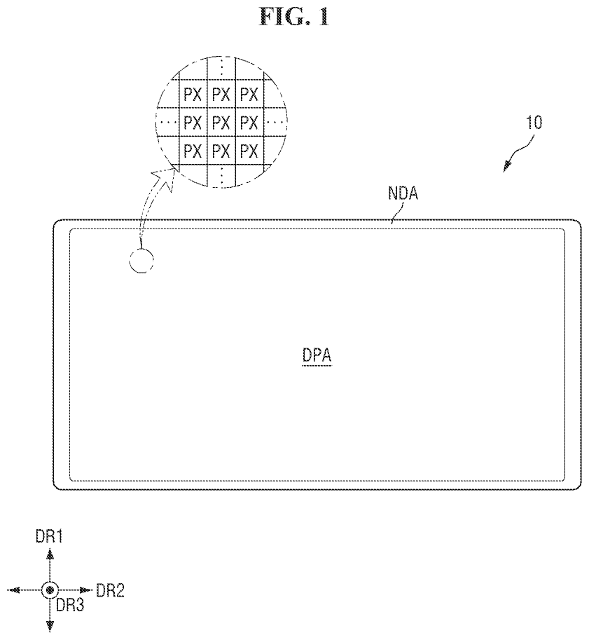

FIG. 1 is a schematic plan view of a display device according to one or more embodiments.

Referring to FIG. 1, a display device 10 displays a moving image or a still image. The display device 10 may refer to any electronic device providing a display screen. Examples of the display device 10 may include a television, a laptop computer, a monitor, a billboard, an Internet-of-Things device, a mobile phone, a smartphone, a tablet personal computer (PC), an electronic watch, a smart watch, a watch phone, a head-mounted display, a mobile communication terminal, an electronic notebook, an electronic book, a portable multimedia player (PMP), a navigation device, a game machine, a digital camera, a camcorder and the like, which provide a display screen.

The display device 10 includes a display panel that provides a display screen. Examples of the display panel may include an inorganic light-emitting diode display panel, an organic light-emitting display panel, a quantum dot light-emitting display panel, a plasma display panel and a field emission display panel. In the following description, a case where an inorganic light-emitting diode display panel is applied as a display panel will be exemplified, but the present disclosure is not limited thereto, and other display panels may be applied within the same scope of the technical spirit.

The shape of the display device 10 may be variously modified. For example, the display device 10 may have a shape, such as a rectangular shape elongated in a horizontal direction, a rectangular shape elongated in a vertical direction, a square shape, a quadrilateral shape with rounded corners (vertices), another polygonal shape, and/or a circular shape. The shape of a display area DPA of the display device 10 may also be similar to the overall shape of the display device 10. FIG. 1 illustrates a display device 10 having a rectangular shape elongated in a second direction DR2.

The display device 10 may include the display area DPA and a non-display area NDA. The display area DPA is an area where a screen can be displayed, and the non-display area NDA is an area where a screen is not displayed. The display area DPA may also be referred to as an active region, and the non-display area NDA may also be referred to as a non-active region. The display area DPA may substantially occupy the center of the display device 10.

The display area DPA may include a plurality of pixels PX. The plurality of pixels PX may be arranged in a matrix. The shape of each pixel PX may be a rectangular or square shape in plan view. However, the present disclosure is not limited thereto, and the shape of each pixel PX may be a rhombic shape in which each side is inclined with respect to one direction. The pixels PX may be located in a stripe type or an island type. In addition, each of the pixels PX may include one or more light-emitting elements that emit light of a corresponding wavelength band to display a corresponding color.

The non-display area NDA may be located around the display area DPA. The non-display area NDA may completely or partially surround the display area DPA. The display area DPA may have a rectangular shape, and the non-display area NDA may be located adjacent to four sides of the display area DPA. The non-display area NDA may form a bezel of the display device 10. Wires or circuit drivers included in the display device 10 may be located in the non-display area NDA, or external devices may be mounted thereon.

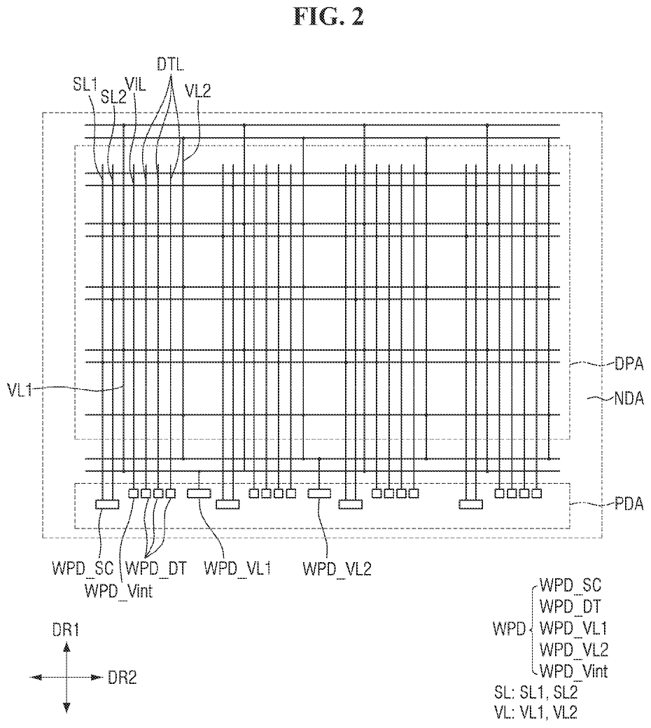

FIG. 2 is a schematic layout view illustrating a plurality of wires of a display device according to one or more embodiments.

Referring to FIG. 2, the display device 10 may include a plurality of wires. The plurality of wires may include a plurality of scan lines SL (e.g., SL1 and SL2), a plurality of data lines DTL, an initialization voltage line VIL, and a plurality of voltage wires VL (e.g., VL1 and VL2). In one or more embodiments, other wires may be further provided in the display device 10.

The plurality of scan lines SL may extend in the first direction DR1. The plurality of scan lines SL may be spaced apart from one another, and may include pairs of a first scan line SL1 and a second scan line SL2. The plurality of scan lines SL may be connected to a scan wire pad WPD_SC connected to a scan driver in one or more embodiments. The plurality of scan lines SL may extend from a pad area PDA located in the non-display area NDA to the display area DPA.

Meanwhile, the term “connected” as used herein may mean not only that one member is connected to another member through a physical contact, but also that one member is connected to another member through yet another member. This may also be understood as one part and the other part as integral elements are connected into an integrated element via another element. Furthermore, if one element is connected to another element, this may be construed as a meaning including an electrical connection via another element in addition to a direct connection in physical contact.

The plurality of data lines DTL may extend in the first direction DR1. The plurality of data lines DTL may include units of three data lines DTL adjacent to one another. The plurality of data lines DTL may extend from the pad area PDA located in the non-display area NDA to the display area DPA.

The initialization voltage line VIL may also extend in the first direction DR1. The initialization voltage line VIL may be located between the data lines DTL and the scan line SL. The initialization voltage line VIL may extend from the pad area PDA, which is located in the non-display area NDA, to the display area DPA.

A first voltage line VL1 and a second voltage line VL2 may include portions extended in the first direction DR1 and portions extended in the second direction DR2. The portions of the first voltage line VL1 and the second voltage line VL2 that extend in the first direction DR1 may traverse the display area DPA. The portions of the voltage line VL1 and the second voltage line VL2 that extend in the second direction DR2 may be located in the display area DPA and may be partially located in the non-display area NDA and located at both sides of the display area DPA with respect to the first direction DR1. The first voltage line VL1 and the second voltage line VL2 may have a mesh structure on the entire display area DPA.

The scan lines SL, the data lines DTL, the initialization voltage line VIL, the first voltage line VL1 and the second voltage line VL2 may be electrically connected to at least one wire pad WPD. The wire pads WPD may be located in the non-display areas NDA. The wire pads WPD may be located in the pad area PDA located on the lower side of the display area DPA that is the opposite side with respect to the first direction DR1, but the present disclosure is not limited thereto. The position of the pad area PDA may vary depending on the size and the specifications of the display device 10. The scan lines SL may be connected to the scan wire pad WPD_SC located in the pad area PDA, and the data lines DTL may be connected to data wire pads WPD_DT, respectively. The initialization voltage line VIL may be connected to the initialization wiring pad WPD_Vint, the first voltage line VL1 may be connected to a first voltage wire pad WPD_VL1, and the second voltage line VL2 may be connected to the second voltage wire pad WPD_VL2. External devices may be mounted on the wire pads WPD. External devices may be mounted on the wire pads WPD by an anisotropic conductive film, ultrasonic bonding, etc. Although the wire pads WPD are located in the pad area PDA located on the lower side of the display area DPA in the drawings, the present disclosure is not limited thereto. Some of the plurality of wire pads WPD may be located on the upper side, the left side, and/or the right side of the display area DPA.

Each of the pixels PX or sub-pixels PXn of the display device 10 includes a pixel driver circuit, where n is an integer of 1 to 3. The above-described lines may pass through each of the pixels PX, or by the periphery thereof, to apply a driving signal to the pixel driver circuit. The pixel driver circuit may include a transistor and a capacitor. The numbers of transistors and capacitors of each pixel driver circuit may be changed in a variety of ways. According to one or more embodiments of the present disclosure, each of the sub-pixels PXn of the display device 10 may have a 3T1C structure (e.g., a pixel driver circuit may include three transistors and one capacitor). In the following description, the pixel driver circuit having the 3T1C structure will be described as an example. However, the present disclosure is not limited thereto. A variety of modified pixel structure may be employed, such as a 2T1C structure, a 7T1C structure and a 6T1C structure.

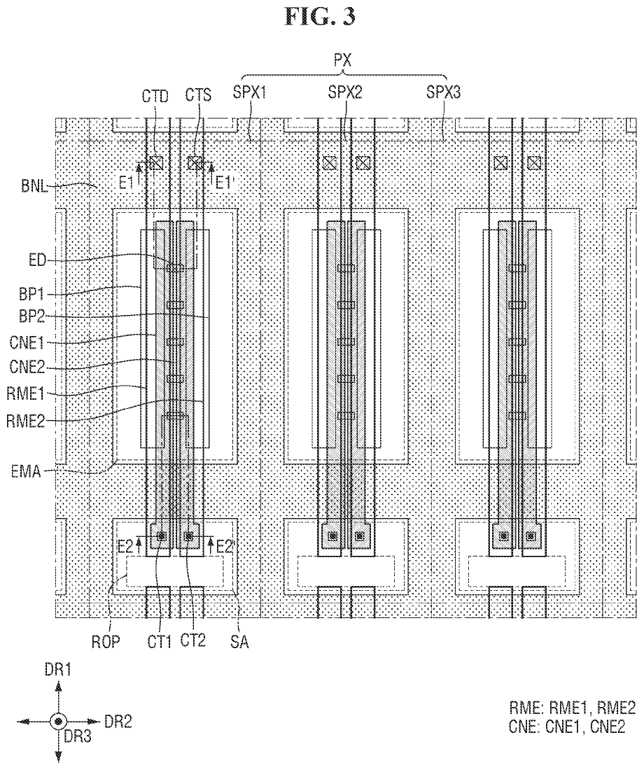

FIG. 3 is a plan view showing a pixel of a display device according to one or more embodiments of the present disclosure. FIG. 3 shows a layout of electrodes RME (e.g., RME1 and RME2), bank patterns BP1 and BP2, a bank layer BNL, light-emitting elements ED (e.g., ED1 and ED2), and connection electrodes CNE (e.g., CNE1 and CNE2) when viewed from the top.

Referring to FIG. 3, each of the pixels PX of the display device 10 may include a plurality of sub-pixels SPXn. For example, a pixel PX may include a first sub-pixel SPX1, a second sub-pixel SPX2, and a third sub-pixel SPX3. The first sub-pixel SPX1 may emit light of a first color, the second sub-pixel SPX2 may emit light of a second color, and the third sub-pixel SPX3 may emit light of a third color. For example, the first color may be red, the second color may be green, and the third color may be blue. Although the single pixel PX includes three sub-pixels SPXn in the example shown in the drawings, the present disclosure is not limited thereto. The pixel PX may include more than three sub-pixels SPXn.

Each of the sub-pixels SPXn of the display device 10 may include an emission area EMA and a non-emission area. In the emission area EMA, where light-emitting elements ED emit light of a corresponding wavelength band. In the non-emission area, the light-emitting elements ED are not present, and the lights emitted from the light-emitting elements ED do not reach the non-emission area, and thus no light exits therefrom.

The emission area EMA may include an area in which the light-emitting elements ED are located, and may include an area adjacent to the light-emitting elements ED where lights emitted from the light-emitting elements ED exit. For example, the emission area EMA may also include an area in which lights emitted from the light-emitting elements ED are reflected or refracted by other elements to exit. The plurality of light-emitting elements ED may be located in each of the sub-pixels SPXn, and the emission area may include the area where the light-emitting elements are located and the adjacent area.

Although the emission areas EMA of the sub-pixels SPXn have the uniform area in the example shown in the drawings, the present disclosure is not limited thereto. In some embodiments, the emission areas EMA of the sub-pixels SPXn may have different respective areas depending on a color or wavelength band of light emitted from the light-emitting elements ED located in the respective sub-pixels.

Each of the sub-pixels SPXn may further include a subsidiary area SA located in the non-emission area. The subsidiary area SA of each sub-pixel SPXn may be located on the lower side of the emission area EMA that is the opposite side in the first direction DR1. The emission areas EMA and the subsidiary areas SA may be arranged alternately in the first direction DR1, and each subsidiary area SA may be located between the emission areas EMA of different sub-pixels SPXn spaced apart from each other in the first direction DR1. For example, the emission areas EMA and the subsidiary areas SA may be alternately arranged in the first direction DR1, and the emission areas EMA and the subsidiary areas SA may be repeatedly arranged in the second direction DR2. However, it is to be understood that the present disclosure is not limited thereto. The emission areas EMA and the subsidiary areas SA of the plurality of pixels PX may have a layout different from that of FIG. 3.

No light-emitting diode ED is located in the subsidiary areas SA, and thus no light exits therefrom. The electrodes RME located in the sub-pixels SPXn may be partially located in the subsidiary areas SA. The electrodes RME located in different sub-pixels SPXn may be separated from one another at separation regions ROP of the subsidiary areas SA.

The display device 10 may include a plurality of electrodes RME (e.g., RME1 and RME2), bank patterns BP1 and BP2, a bank layer BNL, light-emitting elements ED, and connection electrodes CNE (CNE1 and CNE2).

The bank patterns BP1 and BP2 may be located in the emission area EMA of each sub-pixel SPXn. Each of the bank patterns BP1 and BP2 may have a shape that has a constant width in the second direction DR2, and that extends in the first direction DR1.

For example, the bank patterns BP1 and BP2 may include a first bank pattern BP1 and a second bank pattern BP2 spaced apart from each other in the second direction DR2 in the emission area EMA of each sub-pixel SPXn. The first bank pattern BP1 may be located on the left side of the center of the emission area EMA that is one side in the second direction DR2, and the second bank pattern BP2 may be spaced apart from the first bank pattern BP1, and may be located on the right side of the center of the emission area EMA that is the opposite side in the second direction DR2. The first bank pattern BP1 and the second bank pattern BP2 may be alternately arranged along the second direction DR2, and may be located in an island-like pattern in the display area DPA. The plurality of light-emitting elements ED may be located between the first bank pattern BP1 and the second bank pattern BP2.

The length of the first bank pattern BP1 may be substantially equal to the length of the second bank pattern BP2 in the first direction DR1. The lengths of the first bank pattern BP1 and the second bank pattern BP2 may be less than the length of the emission area EMA surrounded by the bank layer BNL in the first direction DR1. The first bank pattern BP1 and the second bank pattern BP2 may be spaced apart from a portion of the bank layer BNL that extends in the second direction DR2. It should be understood, however, that the present disclosure is not limited thereto. The bank patterns BP1 and BP2 may be integrated with the bank layer BNL, or may partially overlap with a portion of the bank layer BNL that extends in the second direction DR2. In this instance, the lengths of the bank patterns BP1 and BP2 in the first direction DR1 may be equal to or greater than the length of the emission area EMA surrounded by the bank layer BNL in the first direction DR1.

The first bank pattern BP1 and the second bank pattern BP2 may have substantially the same width in the second direction DR2. It should be understood, however, that the present disclosure is not limited thereto. They may have different widths. For example, one of the bank patterns may have a greater width than the other one, and the larger bank pattern may be located across the emission areas EMA of different sub-pixels SPXn adjacent to each other in the second direction DR2. In this instance, when the bank patterns are located across the emission areas EMA, portions of the bank layer BNL extended in the first direction DR1 may overlap the second bank pattern BP2 in the thickness direction. Although two bank patterns BP1 and BP2 are located in each sub-pixel SPXn and have substantially the same width in the example shown in the drawings, the present disclosure is not limited thereto. The number and shape of the bank patterns BP1 and BP2 may vary depending on the number or arrangement structure of the electrodes RME.

The plurality of electrodes RME (RME1 and RME2) have a shape extended in one direction, and are located in each of the sub-pixels SPXn. The plurality of electrodes RME1 and RME2 may extend in the first direction DR1 to be located in the emission area EMA and in the subsidiary area SA of the sub-pixel SPXn, and may be spaced apart from one another in the second direction DR2. The plurality of electrodes RME may be electrically connected to the light-emitting elements ED, which will be described later. It should be understood, however, that the present disclosure is not limited thereto. The electrodes RME might not be electrically connected to the light-emitting elements ED.

The display device 10 may include a first electrode RME1 and a second electrode RME2 located in each of the sub-pixels SPXn. The first electrode RME1 is located on the left side of the center of the emission area EMA, and the second electrode RME2 is spaced apart from the first electrode RME1 in the second direction DR2 and is located on the right side of the center of the emission area EMA. The first electrode RME1 may be located on the first bank pattern BP1, and the second electrode RME2 may be located on the second bank pattern BP2. The first electrode RME1 and the second electrode RME2 may extend beyond the bank layer BNL, and may be partially located in the sub-pixel SPXn and the subsidiary area SA. The first electrode RME1 and the second electrode RME2 of a sub-pixel SPXn may be spaced apart from those of another sub-pixel SPXn at the separation region ROP located in the subsidiary area SA of one of the sub-pixels SPXn.

Although two electrodes RME are located in each sub-pixel SPXn, and have a shape extended in the first direction DR1 in the drawings, the present disclosure is not limited thereto. For example, more than two electrodes RME may be located in a single sub-pixel SPXn of the display device 10, or the electrodes RME may be partially bent while having varying widths in a corresponding direction.

The bank layer BNL may surround the plurality of sub-pixels SPXn, the emission area EMA, and the subsidiary area SA. The bank layer BNL may be located at the boundary between the sub-pixels SPXn adjacent to each other in the first direction DR1 and the second direction DR2, and may also be located at the boundary between the emission area EMA and the subsidiary area SA. The sub-pixels SPXn, the emission areas EMA, and the subsidiary areas SA of the display device 10 may be distinguished from one another by the bank layer BNL. The distance between the plurality of sub-pixels SPXn, the emission areas EMA, and the subsidiary areas SA may vary depending on the width of the bank layer BNL.

The bank layer BNL may be located in a lattice pattern on the front surface of the display area DPA including portions extended in the first direction DR1 and the second direction DR2 when viewed from the top. The bank layer BNL may be located along the border of each of the sub-pixels SPXn to distinguish between adjacent sub-pixels SPXn. In addition, the bank layer BNL may surround the emission area EMA and the subsidiary area SA located in each of the sub-pixels SPXn to distinguish between them.

The plurality of light-emitting elements ED may be located in the emission area EMA. The light-emitting elements ED may be located between the bank patterns BP1 and BP2, and may be spaced apart from one another in the first direction DR1. According to one or more embodiments of the present disclosure, the plurality of light-emitting elements ED may have a shape extended in one direction, and the both ends to light-emitting elements ED may be located on different electrodes RME, respectively. The length of the light-emitting elements ED in the second direction DR2 may be larger than the distance between the electrodes RME spaced apart from each other in the second direction DR2. The direction in which the light-emitting elements ED are generally extended may be perpendicular to the first direction DR1 in which the electrodes RME are extended. However, the present disclosure is not limited thereto. The direction in which the light-emitting elements ED extend may face the second direction DR2 or a direction obliquely thereto.

The plurality of connection electrodes CNE (e.g., CNE1 and CNE2) may be located on the plurality of electrodes RME and the bank patterns BP1 and BP2. The plurality of connection electrodes CNE may each have a shape extended in one direction, and may be spaced apart from one another. Each of the connection electrodes CNE may be in contact with the light-emitting elements ED, and may be electrically connected to the electrodes RME or to a conductive layer thereunder.

The connection electrodes CNE may include a first connection electrode CNE1 and a second connection electrode CNE2 located in each sub-pixel SPXn. The first connection electrode CNE1 may have a shape extended in the first direction DR1, and may be located on the first electrode RME1 or the first bank pattern BP1. The first connection electrode CNE1 may partially overlap with the first electrode RME1, and may be located from the emission area EMA to the subsidiary area SA beyond the bank layer BNL. The second connection electrode CNE2 may have a shape extended in the first direction DR1, and may be located on the second electrode RME2 or on the second bank pattern BP2. The second connection electrode CNE2 may partially overlap with the second electrode RME2, and may be located from the emission area EMA to the subsidiary area SA beyond the bank layer BNL.

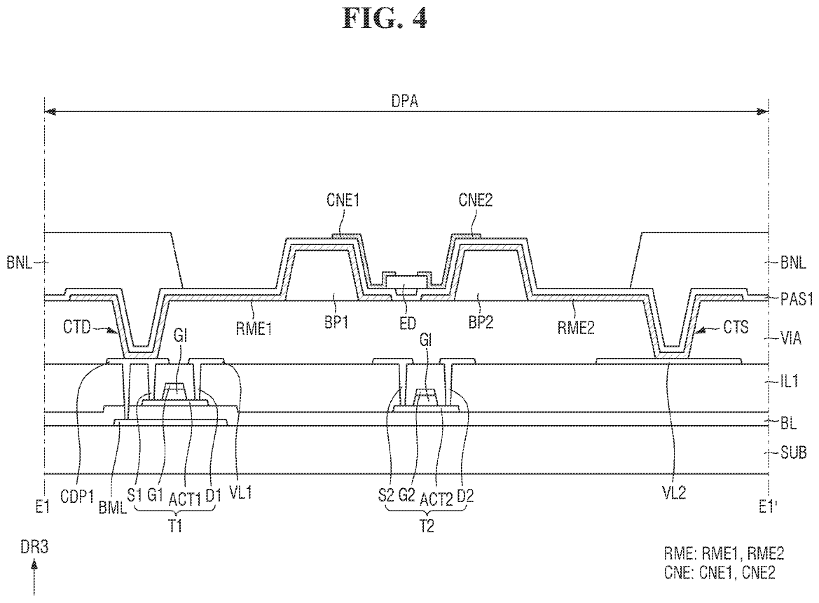

FIG. 4 is a cross-sectional view taken along the line E1-E1′ of FIG. 3. FIG. is a cross-sectional view taken along the line E2-E2′ of FIG. 3.

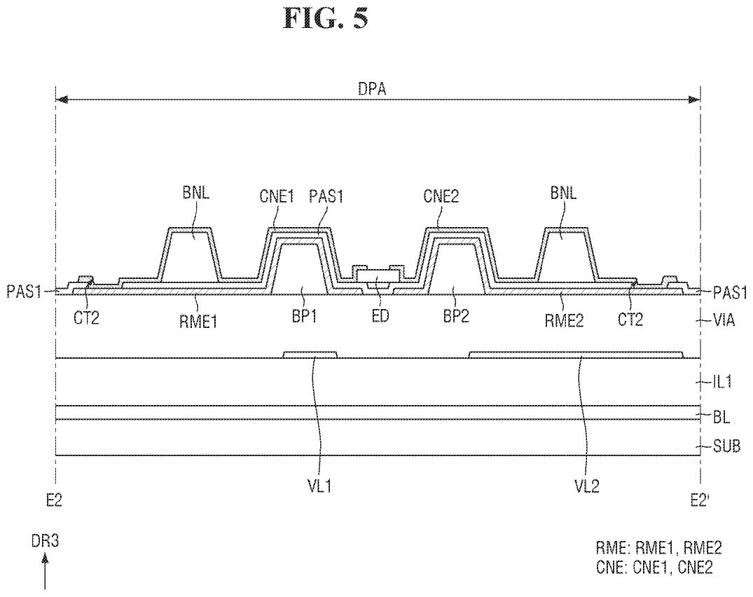

FIG. 4 shows a cross section passing through both ends of the light-emitting elements ED located in the first sub-pixel SPX1 and electrode contact holes CTD and CTS, and FIG. 5 shows a cross section passing through the both ends of the light-emitting elements ED located in the first sub-pixel SPXn and contacts CT1 and CT2.

Referring to FIGS. 3 to 5, the cross-sectional structure of the display device will be described. The display device 10 may include a substrate SUB, and may include a semiconductor layer, a plurality of conductive layers, and a plurality of insulating layers located on the substrate SUB. In addition, the display device 10 may include a plurality of electrodes RME (e.g., RME1 and RME2), light-emitting elements ED, and connection electrodes CNE (e.g., CNE1 and CNE2).

The substrate SUB may be an insulating substrate. The substrate SUB may be made of an insulating material, such as glass, quartz and a polymer resin. The substrate SUB may be either a rigid substrate or a flexible substrate that can be bent, folded, or rolled. The substrate SUB may include the display area DPA, and the non-display area NDA surrounding the display area DPA. The display area DPA may include the emission area EMA and the subsidiary area SA that is a portion of the non-emission area.

A first conductive layer may be located on the substrate SUB. The first conductive layer includes a bottom metal layer BML. The bottom metal layer BML overlaps a first active layer ACT1 of a first transistor T1. The bottom metal layer BML may reduce or prevent light incident on the first active layer ACT1 of the first transistor or may be electrically connected to the first active layer ACT1 to stabilize the electrical characteristics of the first transistor T1. However, the bottom metal layer BML may be omitted in one or more embodiments.

A buffer layer BL may be located on the bottom metal layer BML and the substrate SUB. The buffer layer BL may be formed on the substrate SUB to protect the transistors of the pixels PX from moisture permeating through the substrate SUB that is susceptible to moisture permeation, and may also provide a flat surface.

The semiconductor layer is located on the buffer layer BL. The semiconductor layer may include the first active layer ACT1 of the first transistor T1, and a second active layer ACT2 of a second transistor T2. The first active layer ACT1 and the second active layer ACT2 may partially overlap the first gate electrode G1 and the second gate electrode G2 of a second conductive layer, respectively, which will be described later.

The semiconductor layer may include polycrystalline silicon, monocrystalline silicon, an oxide semiconductor, etc. In other embodiments, the semiconductor layer may include polycrystalline silicon. The oxide semiconductor may be an oxide semiconductor containing indium (In). For example, the oxide semiconductor may be at least one of indium tin oxide (ITO), indium zinc oxide (IZO), indium gallium oxide (IGO), indium zinc tin oxide (IZTO), indium gallium tin oxide (IGTO), indium gallium zinc oxide (IGZO), and/or indium-gallium zinc tin oxide (IGZTO), etc.

Although the first transistor T1 and the second transistor T2 are located in the sub-pixel SPXn of the display device 10 in the drawings, the present disclosure is not limited thereto. A larger number of transistors may be included in the display device 10.

A first gate-insulating layer GI is located on the semiconductor layer in the display area DPA. The first gate-insulating layer GI may function as a gate-insulating film of the transistors T1 and T2. In the example shown in the drawings, the first gate-insulating layer GI is patterned together with the gate electrodes G1 and G2 of the second conductive layer to be described later, and is partially located between the second conductive layer and the active layers ACT1 and ACT2 of the semiconductor layer. However, the present disclosure is not limited thereto. In some embodiments, the first gate-insulating layer GI may be located entirely on the buffer layer BL.

The second conductive layer is located on the first gate-insulating layer GI. The second conductive layer may include a first gate electrode G1 of the first transistor T1, and a second gate electrode G2 of the second transistor T2. The first gate electrode G1 may overlap a channel region of the first active layer ACT1 in a third direction DR3, which is the thickness direction. The second gate electrode G2 may overlap a channel region of the second active layer ACT2 in the third direction DR3, which is the thickness direction.

A first interlayer dielectric layer IL1 is located on the second conductive layer. The first interlayer dielectric layer IL1 may function as an insulating film between the second conductive layer and other layers located thereon, and can protect the second conductive layer.

The third conductive layer is located on the first interlayer dielectric layer IL1. The third conductive layer may include the first voltage line VL1 and the second voltage line VL2 located in the display area DPA, and may include a first conductive pattern CDP1, and may also include the source electrodes S1 and S2 and drain electrodes D1 and D2 of the transistors T1 and T2.

A high-level voltage (or a first supply voltage) may be applied to the first voltage line VL1 to be transmitted to the first electrode RME1, and a low-level voltage (or a second supply voltage) may be applied to the second voltage line VL2 to be transmitted to the second electrode RME2. A portion of the first voltage line VL1 may be in contact with the first active layer ACT1 of the first transistor T1 through a contact hole penetrating the first interlayer dielectric layer IL1. The first voltage line VL1 may function as the first drain electrode D1 of the first transistor T1. The second voltage line VL2 may be directly connected to the second electrode RME2 to be described later.

The first conductive pattern CDP1 may be in contact with the first active layer ACT1 of the first transistor T1 through a contact hole penetrating the first interlayer dielectric layer IL1. The first conductive pattern CDP1 may be in contact with the bottom metal layer BML through another contact hole penetrating the first interlayer dielectric layer IL1 and the buffer layer BL. The first conductive pattern CDP1 may function as a first source electrode S1 of the first transistor T1. In addition, the first conductive pattern CDP1 may be connected to a first electrode RME1 or a first connection electrode CNE1 to be described later. The first transistor T1 may transfer the first supply voltage applied from the first voltage line VL1 to the first electrode RME1 or the first connection electrode CNE1.

Each of the second source electrode S2 and the second drain electrode D2 may be in contact with the second active layer ACT2 of the second transistor T2 through contact holes penetrating the first interlayer dielectric layer IL1.

The buffer layer BL, the first gate-insulating layer GI and the first interlayer dielectric layer IL1 may be made up of multiple inorganic layers alternately stacked on one another. For example, the buffer layer BL, the first gate-insulating layer GI, and the first interlayer dielectric layer IL1 may be made up of a double-layer in which inorganic layers including at least one of silicon oxide (SiOx), silicon nitride (SiNx) and/or silicon oxynitride (SiON) are stacked on one another, or may be made up of multiple layers in which they are alternately stacked on one another. However, the present disclosure is not limited thereto. The buffer layer BL, the first gate-insulating layer GI, and the first interlayer dielectric layer IL1 may be made up of a single inorganic layer including the above-described insulating material. In addition, in some embodiments, the first interlayer dielectric layer IL1 may be made of an organic insulating material, such as polyimide (PI).

A via layer VIA is located on the third conductive layer in the display area DPA. The via layer VIA may include an organic insulating material (e.g., an organic insulating material), such as polyimide (PI), to provide a flat surface over the underlying conductive layers having different heights. It should be noted that the via layer VIA may be eliminated in some implementations.

The display device 10 may include the bank patterns BP1 and BP2, the electrodes RME (RME1 and RME2), the bank layer BNL, the light-emitting elements ED, and the connection electrodes CNE (CNE1 and CNE2) as a display element layer located on the via layer VIA. In addition, the display device 10 may include an insulating layer PAS1 located on the via layer VIA.

The plurality of bank patterns BP1 and BP2 may be located on the via layer VIA. For example, the bank patterns BP1 and BP2 may be located directly on the via layer VIA, and may have a structure that at least partly protrudes from the upper surface of the via layer VIA. The protruding portions of the bank patterns BP1 and BP2 may have inclined side surfaces or bent side surfaces with a curvature (e.g., predetermined curvature). The lights emitted from the light-emitting elements ED may be reflected by the electrodes RME located on the bank patterns BP1 and BP2 so that the lights may exit toward the upper side of the via layer VIA. Unlike that shown in the drawings, the bank patterns BP1 and BP2 may have a shape with a bent outer surface with a curvature, or a predetermined curvature (e.g., a semi-circular or semi-elliptical shape in the cross-sectional view). The bank patterns BP1 and BP2 may include, but is not limited to, an organic insulating material, such as polyimide (PI).

The plurality of electrodes RME1 and RME2 may be respectively located on the bank patterns BP1 and BP2 and the via layer VIA. For example, the first electrode RME1 and the second electrode RME2 may be located on at least inclined side surfaces of the bank patterns BP1 and BP2. The width of the plurality of electrodes RME measured in the second direction DR2 may be less than the width of the bank patterns BP1 and BP2 when measured in the second direction DR2. The distance between the first electrode RME1 and the second electrode RME2 spaced apart from each other in the second direction DR2 may be less than the distance between the bank patterns BP1 and BP2. At least a portion of the first electrode RME1 and the second electrode RME2 may be located directly on the via layer VIA, so that they may be located on the same plane.

The light-emitting elements ED located between the bank patterns BP1 and BP2 may emit lights through both ends. The emitted lights may be directed to the electrodes RME located on the bank patterns BP1 and BP2. The portion of each of the electrodes RME that is located on the bank patterns BP1 and BP2 may reflect lights emitted from the light-emitting elements ED. The first electrode RME1 and the second electrode RME2 may cover at least one side surface of the bank patterns BP1 and BP2 to reflect lights emitted from the light-emitting elements ED.

Each of the electrodes RME may be in direct contact with the third conductive layer through the electrode contact holes CTD and CTS where it overlaps with the bank layer BNL that is between the emission area EMA and the subsidiary area SA. The first electrode contact hole CTD may be formed where the bank layer BNL and the first electrode RME1 overlap each other. The second electrode contact hole CTS may be formed where the bank layer BNL and the second electrode RME2 overlap each other. The first electrode RME1 may be in contact with the first conductive pattern CDP1 through the first electrode contact hole CTD penetrating through the via layer VIA. The second electrode RME2 may be in contact with the second voltage line VL2 through the second electrode contact hole CTS penetrating through the via layer VIA. The first electrode RME1 may be electrically connected to the first transistor T1 through the first conductive pattern CDP1 to receive the first supply voltage. The second electrode RME2 may be electrically connected to the second voltage line VL2 to receive the second supply voltage. However, the present disclosure is not limited thereto. According to one or more other embodiments, each of the electrodes RME1 and RME2 may be electrically insulated from the voltage lines VL1 and VL2 of the third conductive layer, and connection electrodes CNE to be described later may be directly connected to the third conductive layer.

Each of the electrodes RME may include a conductive material having a high reflectance. For example, the electrodes RME may include a metal, such as silver (Ag), copper (Cu) and aluminum (Al), or may include an alloy including aluminum (Al), nickel (Ni), lanthanum (La), or the like, or a stack of a metal layer, such as titanium (Ti), molybdenum (Mo) and niobium (Nb) and the alloy. In some embodiments, the electrodes RME may be made up of a double- or multi-layer in which an alloy containing aluminum (Al) and at least one metal layer made of titanium (Ti), molybdenum (Mo) and niobium (Nb) are stacked on one another.

However, the present disclosure is not limited thereto. The electrodes RME may further include a transparent conductive material. For example, each of the electrodes RME may include a material, such as ITO, IZO and ITZO. In some embodiments, each of the electrodes RME1 and RME2 may have a structure in which one or more layers of a transparent conductive material, and one or more metal layers having high reflectivity, are stacked on one another, or may be made up of a single layer including them. For example, each of the electrodes RME may have a stack structure, such as ITO/Ag/ITO/, ITO/Ag/IZO, or ITO/Ag/ITZO/IZO. The electrodes RME may be electrically connected to the light-emitting elements ED, and may reflect some of the lights emitted from the light-emitting elements ED toward the upper side of the substrate SUB.

The first insulating layer PAS1 may be located on the front surface of the display area DPA, and may be located on the via layer VIA and the plurality of electrodes RME. The first insulating layer PAS1 may include an insulating material, and can protect the plurality of electrodes RME and can insulate different electrodes RME from each other. As the first insulating layer PAS1 covers the electrodes RME before the bank layer BNL is formed, it is possible to reduce or prevent the likelihood of the electrodes RME being damaged during the process of forming the bank layer BNL. In addition, the first insulating layer PAS1 can also reduce or prevent the likelihood that the light-emitting elements ED located thereon are brought into contact with other elements and damaged.

In one or more embodiments, the first insulating layer PAS1 may have steps so that a portion of the upper surface is recessed between the electrodes RME spaced apart from one another in the second direction DR2. The light-emitting elements ED may be located at the steps of the upper surface of the first insulating layer PAS1, and space may be formed between the light-emitting elements ED and the first insulating layer PAS1. The first insulating layer PAS1 may fill the space.

The first insulating layer PAS1 may include contacts CT1 and CT2 located in the subsidiary area SA. The contacts CT1 and CT2 may overlap different electrodes RME, respectively. For example, the contacts CT1 and CT2 may include first contacts CT1 overlapping the first electrode RME1, and second contacts CT2 overlapping the second electrode RME2. The first contacts CT1 and the second contacts CT2 may penetrate the first insulating layer PAS1 to expose a portion of the upper surface of the first electrode RME1 or the second electrode RME2 located thereunder. Each of the first contact CT1 and the second contact CT2 may further penetrate some of the other insulating layers located on the first insulating layer PAS1. The electrodes RME exposed by the contacts CT1 and CT2 may be in contact with the connection electrodes CNE.

According to one or more embodiments, the first insulating layer PAS1 may include an organic material in which a light-blocking material capable of blocking light is dispersed. The first insulating layer PAS1 may have a black color.

The light-blocking material may include a black pigment. The black pigment may include, for example, at least one selected from the group consisting of aniline black, perylene black, titanium black, and carbon black. For example, the black pigment may be carbon black. For example, carbon black may include channel black, furnace black, thermal black, lamp black, and the like, and may be used alone or in combination of two or more. The organic material may include a polymer resin. The polymer resin may include an acrylic resin. For example, the acrylic resin may be a copolymer of a carboxyl group-containing monomer and another copolymerizable monomer.

However, the present disclosure is not limited thereto and the light-blocking material may include an opaque material, such as metal particles like nickel, aluminum, molybdenum and alloys thereof, metal oxide particles (e.g., chromium oxide), or metal nitride particles (e.g., chromium nitride). In addition, the organic material is not limited to the acrylic resin and can be applied as long as it can act as an organic material layer, such as an imide-based resin.

As described above, the electrodes RME may include a conductive material having a high reflectivity, and thus light incident from the outside may be reflected by the electrodes RME to deteriorate display quality. In one or more embodiments, the first insulating layer PAS1 including a light-blocking material may be formed. The first insulating layer PAS1 covers most of the display area DPA and covers the electrodes RME, thereby reducing or preventing external light reflected from the electrodes RME. Accordingly, the reflectance may be reduced to improve the display quality of the display device 10.

Meanwhile, the bank layer BNL may be located on the first insulating layer PAS1. The bank layer BNL may include portions extended in the first direction DR1 and the second direction DR2, and may surround each of the sub-pixels SPXn. The bank layer BNL may surround the emission area EMA and the subsidiary area SA of each of the sub-pixels SPXn to distinguish between them, and may surround the border of the display area DPA to distinguish between the display area DPA and the non-display area NDA.

The bank layer BNL may have a height (e.g., predetermined height) that is substantially similar to the bank patterns BP1 and BP2. In some embodiments, the top surface of the bank layer BNL may have a height that is greater than a height of the bank patterns BP1 and BP2, and the thickness thereof may be equal to or greater than the thicknesses of the bank patterns BP1 and BP2. The bank layer BNL can reduce or prevent the likelihood of an ink overflowing into adjacent sub-pixels SPXn during an inkjet printing process of the process of fabricating the display device 10. The bank layer BNL may include an organic insulating material, such as polyimide, like the bank patterns BP1 and BP2.

The plurality of light-emitting elements ED may be located in the emission area EMA. The light-emitting elements ED may be located on the first insulating layer PAS1 between the bank patterns BP1 and BP2. The direction in which the light-emitting elements ED extend may be substantially parallel to the upper surface of the substrate SUB. As will be described later, the light-emitting elements ED may include a plurality of semiconductor layers arranged in the extended direction. The plurality of semiconductor layers may be sequentially arranged along a direction that is substantially parallel to the upper surface of the substrate SUB. It should be understood, however, that the present disclosure is not limited thereto. When the light-emitting elements ED have a different structure, a plurality of semiconductor layers may be located in a direction that is substantially perpendicular to the substrate SUB.

The light-emitting elements ED located in each of the sub-pixels SPXn may emit light of different respective wavelength bands depending on the material of the semiconductor layer. For example, the light-emitting element ED located in the first sub-pixel SPX1 may emit red light of a first color, the light-emitting element ED located in the second sub-pixel SPX2 may emit green light of a second color, and the light-emitting element ED located in the third sub-pixel SPX3 may emit blue light of a third color.

When the light-emitting devices ED include indium among semiconductor materials included in an emissive layer 36 to be described later, the color of the emitted light may vary according to the content of indium. For example, when the content of indium is about 10% to about 15%, blue light of the third color may be emitted, and when the content of indium is about 20% to about 25%, green light of the second color may be emitted. And, when the content of indium is about 30% to about 45%, red light of the first color of may be emitted.

The light-emitting elements ED may be electrically connected to the electrodes RME and the conductive layers under the via layer VIA in contact with the connection electrodes CNE1 and CNE2, and an electric signal may be applied to it so that light of a corresponding wavelength range can be emitted.

The plurality of connection electrodes CNE1 and CNE2 may be located on the plurality of electrodes RME1 and RME2 and the bank patterns BP1 and BP2. The first connection electrode CNE1 may be located on the first electrode RME1 and the first bank pattern BP1. The first connection electrode CNE1 may partially overlap with the first electrode RME1, and may be located from the emission area EMA to the subsidiary area SA beyond the bank layer BNL. The second connection electrode CNE2 may be located on the second electrode RME2 and the second bank pattern BP2. The second connection electrode CNE2 may partially overlap with the second electrode RME2, and may be located from the emission area EMA to the subsidiary area SA beyond the bank layer BNL.

Each of the first connection electrode CNE1 and the second connection electrode CNE2 may be located on the first insulating layer PAS1, and may be in contact with the light-emitting elements ED. The first connection electrode CNE1 may partially overlap with the first electrode RME1, and may be in contact with first ends of the light-emitting elements ED. The second connection electrode CNE2 may partially overlap with the second electrode RME2, and may be in contact with second ends of the light-emitting elements ED. The plurality of connection electrodes CNE are located across the emission area EMA and the subsidiary area SA. A portion of each of the connection electrodes CNE that is located in the emission area EMA may be in contact with the light-emitting elements ED, and a part thereof that is located in the subsidiary area SA may be electrically connected to the third conductive layer. The first connection electrode CNE1 may be in contact with the first ends of the light-emitting elements ED, and the second connection electrode CNE2 may be in contact with the second ends of the light-emitting elements ED.

In the display device, each of the connection electrodes CNE may be in contact with the electrodes RME through the contacts CT1 and CT2 located in the subsidiary area SA. The first connection electrode CNE1 may be in contact with the first electrode RME1 through the first contact CT1 penetrating the first insulating layer PAS1 in the subsidiary area SA. The second connection electrode CNE2 may be in contact with the second electrode RME2 through the second contact CT2 penetrating the first insulating layer in the subsidiary area SA. The connection electrodes CNE may be electrically connected to the third conductive layer through the respective electrodes RME. The first connection electrode CNE1 may be electrically connected to the first transistor T1 to apply the first supply voltage, and the second connection electrode CNE2 may be electrically connected to the second voltage line VL2 to apply the second supply voltage. Each of the connection electrodes CNE may be in contact with the light-emitting elements ED in the emission area EMA to transmit the supply voltage to the light-emitting elements ED.

However, the present disclosure is not limited thereto. In some embodiments, the plurality of connection electrodes CNE may be in direct contact with the third conductive layer, or may be electrically connected to the third conductive layer through other patterns than the electrodes RME.

The connection electrodes CNE may include a conductive material. For example, the connection electrodes CNE may include ITO, IZO, ITZO, aluminum (Al), etc. For example, the connection electrodes CNE may include a transparent conductive material, and lights emitted from the light-emitting elements ED may transmit the connection electrodes CNE to exit.

In one or more embodiments, another insulating layer may be further located on the first insulating layer PAS1, and the connection electrodes CNE. The insulating layer can protect the elements located on the substrate SUB against the external environment.

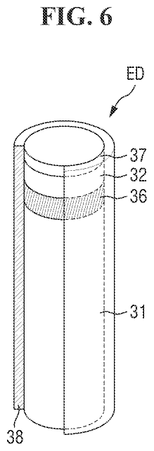

FIG. 6 is a schematic view of a light-emitting element according to one or more embodiments.

Referring to FIG. 6, a light-emitting element ED may be a light-emitting diode. For example, the light-emitting element ED may have a size in a range from nanometers to micrometers, and may be an inorganic light-emitting diode made of an inorganic material. The light-emitting element ED may be aligned between two electrodes facing each other when polarities are created by forming an electric field in a corresponding direction between the two electrodes.

The light-emitting element ED according to one or more embodiments may have a shape extended in one direction. The light-emitting element ED may have a shape of a cylinder, a rod, a wire, a tube, etc. It is to be understood that the shape of the light-emitting diode ED is not limited thereto. The light-emitting diode ED may have a variety of shapes including a polygonal column shape, such as a cube, a cuboid and a hexagonal column, or a shape that extends in a direction with partially inclined outer surfaces.

The light-emitting element ED may include semiconductor layers doped with a dopant of a conductive type (e.g., p-type or n-type). The semiconductor layers may emit light of a certain wavelength band by transmitting an electric signal applied from an external power source. The light-emitting element ED may include a first semiconductor layer 31, a second semiconductor layer 32, an emissive layer 36, an electrode layer 37, and an insulating film 38.

The first semiconductor layer 31 may be an n-type semiconductor. The first semiconductor layer 31 may include a semiconductor material having the following chemical formula: AlxGayIn1−x−yN (0≤x≤1, 0≤x+y≤1). For example, the first semiconductor layer 31 may be one or more of AlGaInN, GaN, AlGaN, InGaN, AlN and InN doped with n-type dopant. The n-type dopant doped into the first semiconductor layer 31 may be Si, Ge, Sn, Se, etc.

The second semiconductor layer 32 is located above the first semiconductor layer 31 with the emissive layer 36 therebetween. The second semiconductor layer 32 may be a p-type semiconductor, and may include a semiconductor material having the following chemical formula: AlxGayIn1−x−yN (0≤x≤1, 0≤y≤1, 0≤x+y≤1). For example, the second semiconductor layer 32 may be one or more of AlGaInN, GaN, AlGaN, InGaN, AlN and InN doped with p-type dopant. The p-type dopant doped into the second semiconductor layer 32 may be Mg, Zn, Ca, Ba, etc.

Although each of the first semiconductor layer 31 and the second semiconductor layer 32 is implemented as a signal layer in the drawings, the present disclosure is not limited thereto. Depending on the material of the emissive layer 36, the first semiconductor layer 31 and the second semiconductor layer 32 may further include a larger number of layers, e.g., a clad layer or a tensile strain barrier reducing (TSBR) layer. For example, the light-emitting elements ED may further include another semiconductor layer located between the first semiconductor layer 31 and the emissive layer 36 or between the second semiconductor layer 32 and the emissive layer 36. The semiconductor layer located between the first semiconductor layer 31 and the emissive layer 36 may be one or more of AlGaInN, GaN, AlGaN, InGaN, AlN, InN and SLs doped with an n-type dopant. The semiconductor layer located between the second semiconductor layer 32 and the emissive layer 36 may be one or more of AlGaInN, GaN, AlGaN, InGaN, AlN, and InN doped with a p-type dopant.

The emissive layer 36 is located between the first semiconductor layer 31 and the second semiconductor layer 32. The emissive layer 36 may include a material having a single or multiple quantum well structure. When the emissive layer 36 includes a material having the multiple quantum well structure, the structure may include quantum layers and well layers alternately stacked on one another. The emissive layer 36 may emit light as electron-hole pairs are combined therein in response to an electrical signal applied through the first semiconductor layer 31 and the second semiconductor layer 32. The emissive layer 36 may include a material, such as AlGaN, AlGaInN, and InGaN. For example, when the emissive layer 36 has a multi-quantum well structure in which quantum layers and well layers are alternately stacked on one another, the quantum layers may include AlGaN or AlGaInN, and the well layers may include a material, such as GaN and AlGaN.

The emissive layer 36 may have a structure in which a semiconductor material having a large band gap energy and a semiconductor material having a small band gap energy are alternately stacked on one another, and may include other Group III to Group V semiconductor materials depending on the wavelength range of the emitted light. The emissive layer 36 may emit light of red, green, or blue wavelength band.

The electrode layer 37 may be an ohmic connection electrode. However, the present disclosure is not limited thereto. The electrode layer 37 may be a Schottky connection electrode. The light-emitting element ED may include at least one electrode layer 37. The light-emitting element ED may include one or more electrode layers 37. However, the present disclosure is not limited thereto. The electrode layer 37 may be eliminated.

The electrode layer 37 can reduce the resistance between the light-emitting element ED and the electrodes or the connection electrodes when the light-emitting element ED is electrically connected to the electrodes or the connection electrodes in the display device 10. The electrode layer 37 may include a metal having conductivity. For example, the electrode layer 37 may include at least one of aluminum (Al), titanium (Ti), indium (In), gold (Au), silver (Ag), ITO, IZO and/or ITZO.

The insulating film 38 surrounds the outer surfaces of the plurality of semiconductor layers and electrode layers described above. For example, the insulating film 38 may surround at least the outer surface of the emissive layer 36, with both ends of the light-emitting element ED in the longitudinal direction exposed. In addition, a portion of the upper surface of the insulating film 38 may be rounded in cross section, which is adjacent to at least one of the ends of the light-emitting element ED.

The insulating film 38 may include materials having insulating properties, for example, at least one of silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), and/or titanium oxide (TiOx). Although the insulating film 38 is formed as a single layer in the drawings, the present disclosure is not limited thereto. In some embodiments, the insulating film 38 may be made up of a multilayer structure in which multiple layers are stacked on one another.

The insulating film 38 can protect the semiconductor layers and the electrode layer of the light-emitting elements ED. The insulating film 38 can reduce or prevent the likelihood of an electrical short-circuit occurring in the emissive layer 36 if it comes in direct contact with an electrode through which an electric signal is transmitted to the light-emitting element ED. In addition, the insulating film 38 can reduce or prevent a decrease in luminous efficiency.

In addition, the outer surface of the insulating film 38 may be subjected to surface treatment. The light-emitting elements ED may be dispersed in an ink, and the ink may be sprayed onto the electrode. In doing so, a surface treatment may be applied to the insulating film 38 so that it becomes hydrophobic or hydrophilic in order to keep the light-emitting elements ED dispersed in the ink from being aggregated with one another.

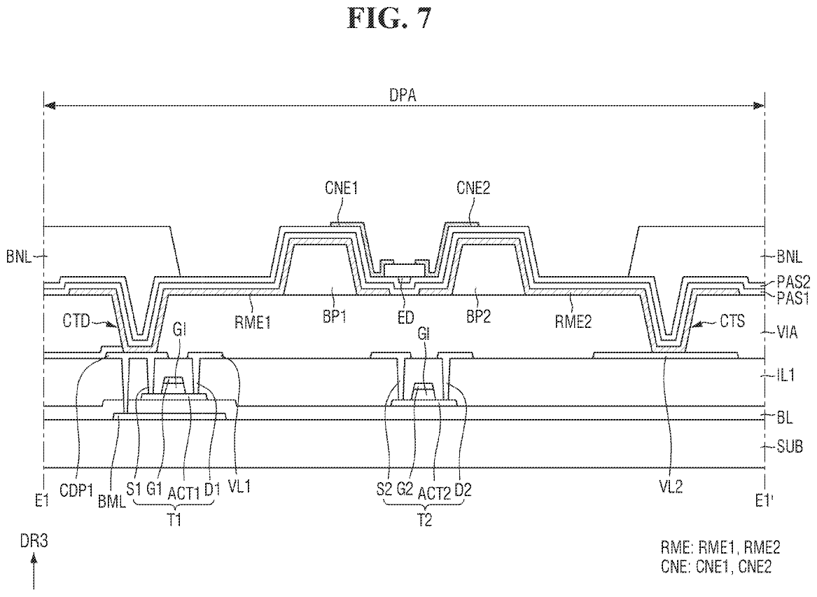

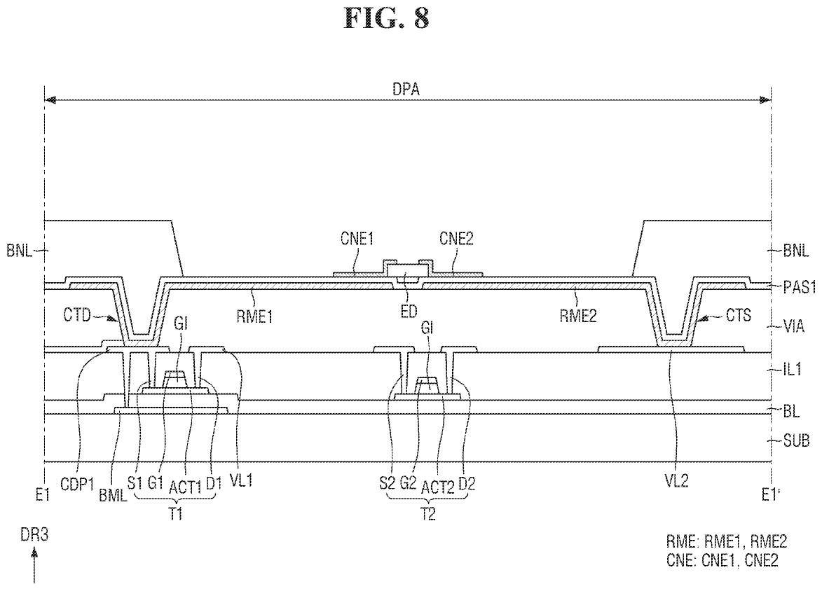

FIG. 7 is a cross-sectional view of a display device according to one or more other embodiments. FIG. 8 is a cross-sectional view of a display device according to still yet one or more other embodiments.

Referring to FIG. 7, the present embodiments are different from FIGS. 3 to 5 in that they further include a second insulating layer PAS2 between the first insulating layer PAS1 and the connection electrodes CNE. Hereinafter, a description of the same configuration as in the embodiments of FIGS. 3 to 5 will be omitted and differences will be described.

The second insulating layer PAS2 may be located on the first insulating layer PAS1. The second insulating layer PAS2 may be located between the first insulating layer PAS1 and the light-emitting elements ED, and between the first insulating layer PAS1 and the connection electrodes CNE. The second insulating layer PAS2 may be located in substantially the same shape as the first insulating layer PAS1. For example, the second insulating layer may be located on the front surface of the display area DPA and may be directly on the first insulating layer PAS1. The second insulating layer PAS2 may be in contact with the top surface of the first insulating layer PAS1 and the bottom surface of the light-emitting element ED. In one or more embodiments, the second insulating layer PAS2 may completely overlap the first insulating layer PAS1.

The second insulating layer PAS2 may include an inorganic insulating material to protect the plurality of electrodes RME, and may substantially simultaneously insulate different electrodes RME from each other. The second insulating layer PAS2 may cover the first insulating layer PAS1 including an organic material to protect it from external moisture. In addition, in the second insulating layer PAS2, the likelihood of the electric field, which is formed between the electrodes RME during the alignment process of the light-emitting element ED, being affected by the difference in permittivity of the first insulating layer PAS1, which includes the organic material, may be reduced or prevented.

The second insulating layer PAS2 may include an inorganic insulating material. For example, the second insulating layer PAS2 may be any one of silicon oxide (SiOx), silicon nitride (SiNx), and silicon oxynitride (SiOxNy). The second insulating layer PAS2 may have a multilayer structure in which one layer or a plurality of insulating layers are stacked alternately or repeatedly.

The light-emitting element ED may be directly located on the second insulating layer PAS2. In one or more embodiments, the second insulating layer PAS2 connects the contacts (e.g., contacts CT1 and CT2 of FIG. 3) located in the subsidiary area (e.g., subsidiary area SA of FIG. 3) in the same manner as the first insulating layer PAS1. The contacts CT1 and CT2 may penetrate the first insulating layer PAS1 and the second insulating layer PAS2 to expose a portion of the upper surface of the first electrode RME1 or the second electrode RME2 thereunder. The electrode RME exposed by each of the contacts CT1 and CT2 may be in contact with the connection electrode CNE.

The plurality of connection electrodes CNE may be located on the second insulating layer PAS2 and the light-emitting element ED. For example, the first connection electrode CNE1 may be located directly on the second insulating layer PAS2, and may extend from one end of the light-emitting element ED. The second connection electrode CNE2 may be located directly on the second insulating layer PAS2, and may extend from the other end of the light-emitting element ED.

Referring to FIG. 8, the bank patterns BP1 and BP2 may be omitted in the display device 10 in embodiments of RCS. 3 to 5. In this instance, the electrodes RME may be directly located on the via layer VIA to be formed substantially flat.

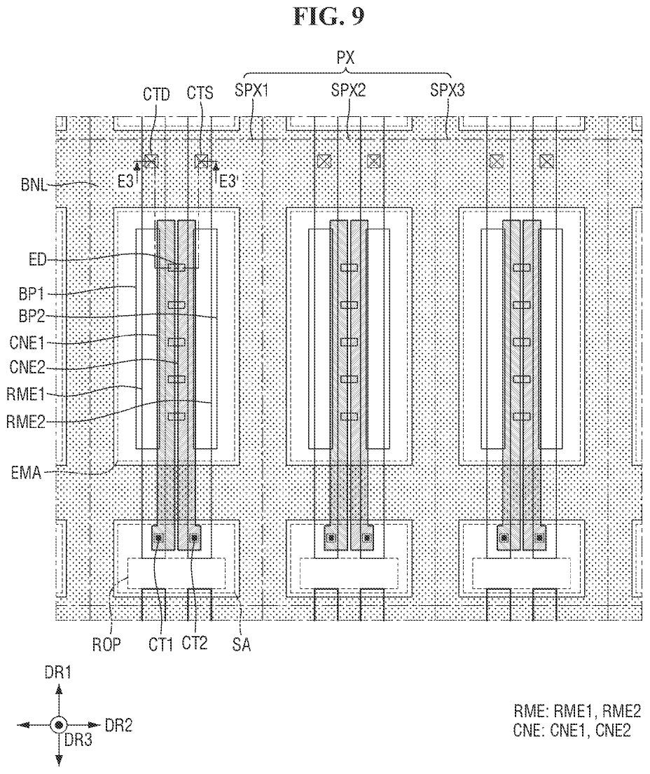

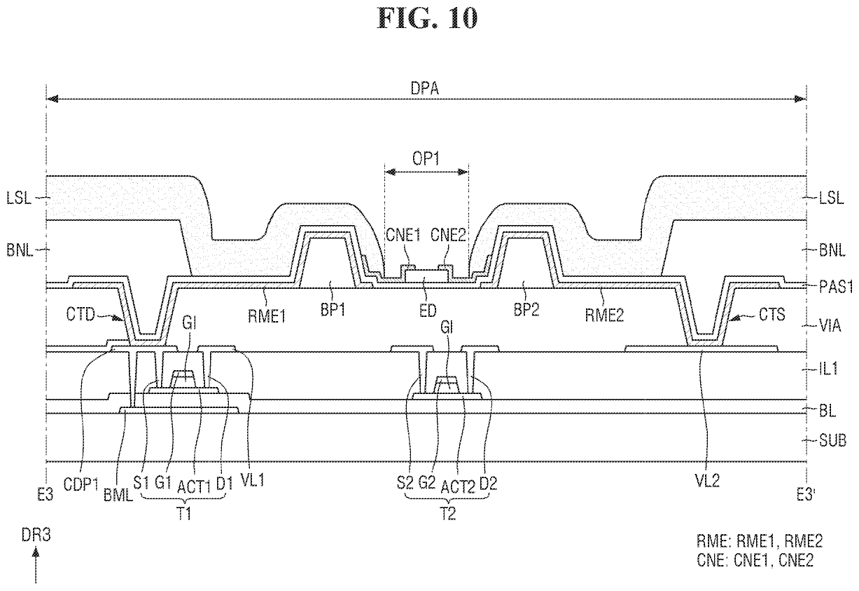

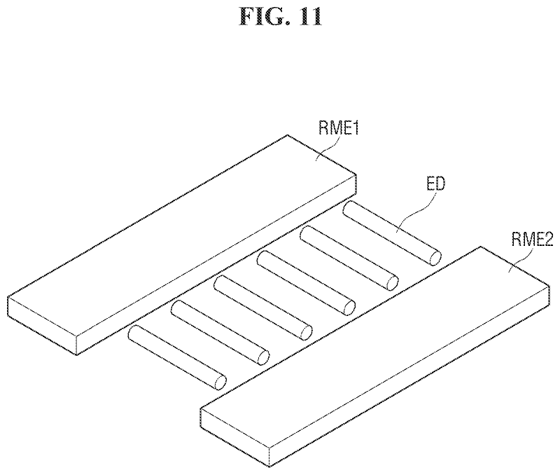

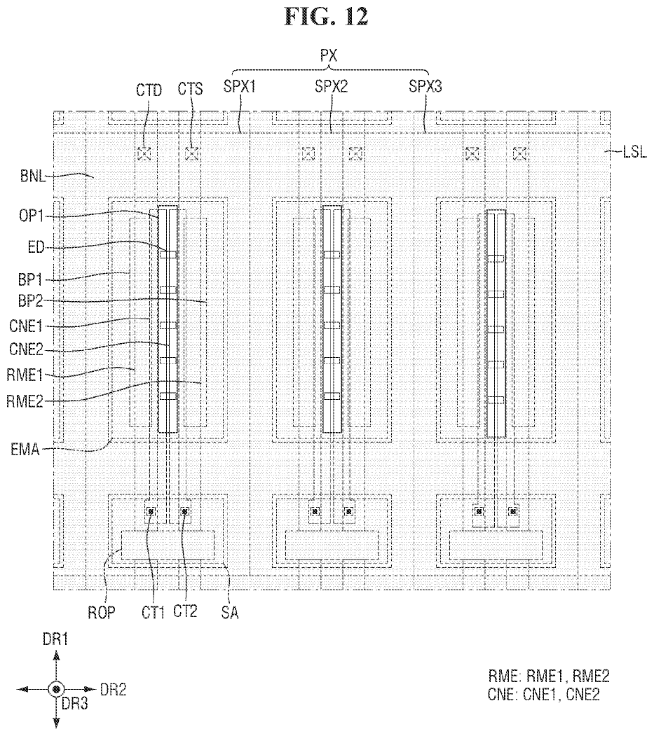

FIG. 9 is a plan view illustrating one pixel of a display device according to one or more embodiments. FIG. 10 is a cross-sectional view taken along the line E3-E3′ of FIG. 9. FIG. 11 is a view schematically illustrating electrodes and light-emitting elements according to yet one or more other embodiments. FIG. 12 is a plan view illustrating a light-blocking layer in one sub-pixel of a display device according to yet one or more other embodiments.

Referring to FIGS. 9 to 12, the present embodiments are different from the embodiments of FIGS. 3 to 5 described above in that it further includes a light-blocking layer LSL entirely covering the display area DPA, and including/defining a first opening OP1 that exposes the plurality of light-emitting elements ED (e.g.; the light-blocking layer LSL might not overlap the light-emitting elements ED), and in that the first insulating layer PAS1 is formed of a transparent insulating material. Hereinafter, a repeated description of the same configuration as in the embodiments of FIGS. 3 to 5 will be omitted, and differences will be described.

Electrodes RME may be located on the via layer VIA. The first insulating layer PAS1 may be located on the electrodes RME. Unlike the above-described embodiments of FIGS. 3 to 5, the first insulating layer PAS1 may be made of a transparent insulating material. The first insulating layer PAS1 may be formed of, for example, the same material as the second insulating layer PAS2 of FIG. 6. Further, the second insulating layer PAS2 might not include a light-blocking material.

The plurality of light-emitting elements ED may be located on the first insulating layer PAS1. The plurality of light-emitting elements ED may be located in the emission area EMA. The light-emitting elements ED may be located between the bank patterns BP1 and BP2, and may be arranged to be spaced apart from each other in the first direction DR1. In one or more embodiments, the plurality of light-emitting elements ED may have a shape extending in one direction, and might not overlap the electrodes RME. For example, the light-emitting elements ED may be spaced apart from the first electrode RME1 and the second electrode RME2 in a plan view. A distance between the electrodes RME may be greater than a length of the light-emitting elements ED in the second direction DR2. Connection electrodes CNE may be located on the light-emitting elements ED and the first insulating layer PAS1.

According to one or more embodiments, a light-blocking layer LSL may be located on the bank layer BNL, the first insulating layer PAS1, and the connection electrodes CNE. The light-blocking layer LSL may be entirely located on the display area DPA. The light-blocking layer LSL may overlap a portion of the first connection electrode CNE1 and the first electrode RME1, and may overlap a portion of the second connection electrode CNE2 and the second electrode RME2. For example, the light-blocking layer LSL may overlap the entire first electrode RME1 and the second electrode RME2 in one or more embodiments.

The light-blocking layer LSL may include/define a first opening(s) exposing the plurality of light-emitting elements ED in the emission area EMA. The first opening OP1 allows light emitted from the plurality of light-emitting elements ED to be emitted. The first opening OP1 may expose a portion of the first connection electrode CNE1, a portion of the second connection electrode CNE2, and a portion of the first insulating layer PAS1 in addition to the plurality of light-emitting elements ED. In addition, the light-blocking layer LSL may cover the entire emission area EMA and the subsidiary area SA except for the first opening OP1.

According to one or more embodiments, a light-blocking layer LSL may include an organic material including a light-blocking material capable of blocking light. The light-blocking layer LSL may have a black color. The light-blocking layer LSL may be formed of the same material as the first insulating layer PAS1 of the above-described embodiments of FIGS. 3 to 5.

As described above, the electrodes RME may include a conductive material having a relatively high reflectivity, and thus, light incident from the outside may be reflected by the electrodes RME to deteriorate display quality. In addition, wirings (e.g., various wirings illustrated in FIG. 2) located in the display area DPA other than the electrodes RME may be made of metal to reflect light. In one or more embodiments, the light-blocking layer LSL including the light-blocking material may be formed. The light-blocking layer LSL covers most of the display area DPA, and covers not only the electrodes RME of the emission area EMA, but also covers the wirings of the non-emission area, thereby reducing or preventing the likelihood of the external light being reflected from the electrodes RME and the wirings. Accordingly, the reflectance may be reduced to improve the display quality of the display device 10.

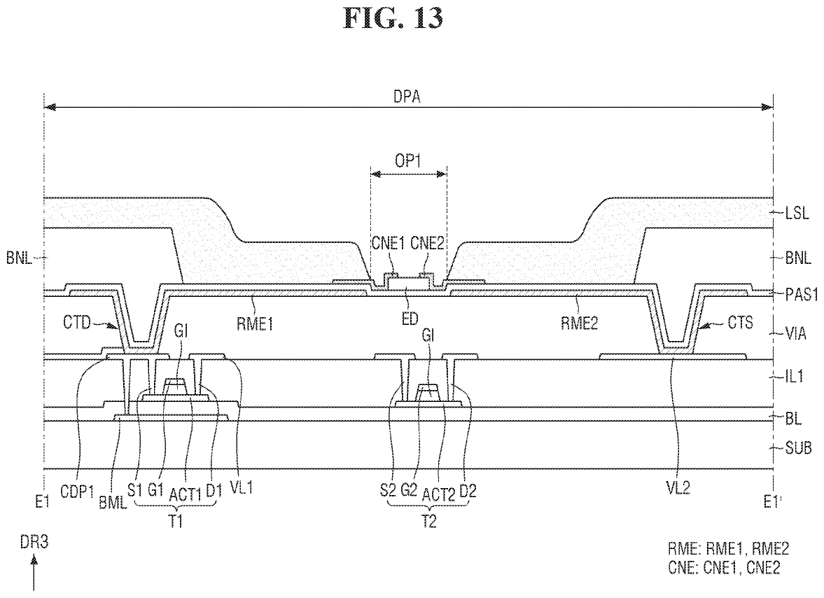

FIG. 13 is a cross-sectional view of a display device according to yet one or more other embodiments.

Referring to FIG. 13, the present embodiments are different from the above-described embodiments of FIGS. 9 to 12 in that the first bank pattern BP1 and the second bank pattern BP2 are omitted. In this case, process characteristics may be achieved because the electrodes RME may be located directly on the via layer VIA to be substantially flat, and the bank patterns BP1 and BP2 may be omitted so that the light-blocking layer LSL located thereon is substantially flat.

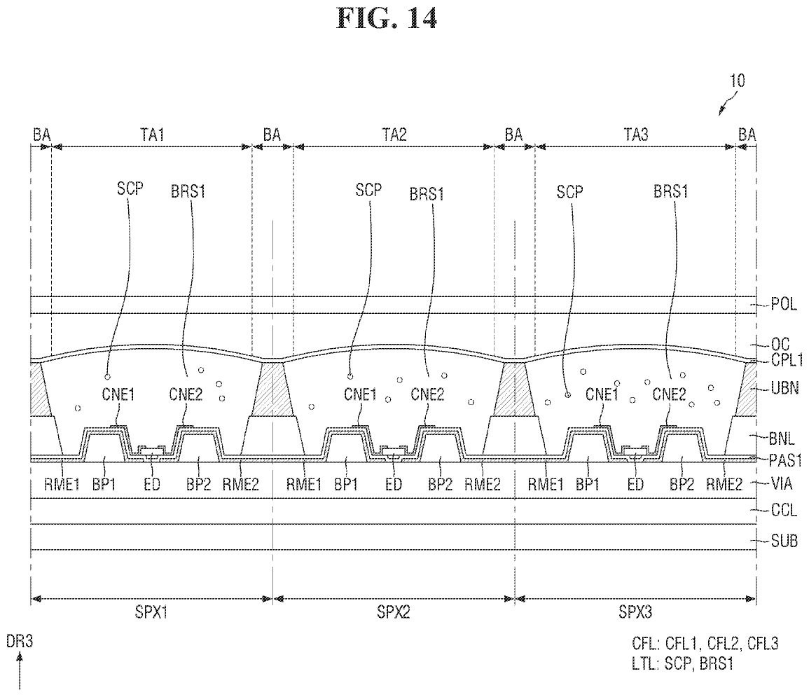

FIG. 14 is a cross-sectional view of a display device according to one or more embodiments.

Referring to FIG. 14, the display device 10 may include light-emitting elements ED located on a substrate SUB, and a light-transmissive layer LTL (e.g., a first base resin BRS1 and scatterers SCP) located over them. In addition, the display device 10 may further include a plurality of layers located between the light-transmissive layer LTL. Hereinafter, layers located over the light-emitting elements ED of the display device 10 will be described. In Fla 14, the description is directed to the substrate SUB shown in Fla 4 and components located on the substrate SUB.

An upper bank layer UBN and a light-transmissive layer LTL may be located on the bank layer BNL, the first insulating layer PAS1 and the connection electrodes CNE. A first capping layer CPL1 may be located on the light-transmissive layer LTL, and an overcoat layer OC may be located on the first capping layer CPL1. A polarizing plate POL may be located on the overcoat layer OC.

The display device 10 may include a plurality of light-transmitting areas TA1, TA2, and TA3 where the upper bank layer UBN emits light, and a light-blocking area BA from which light is not emitted between the light-transmitting areas TA1, TA2, and TA3. The light-transmitting areas TA1, TA2, and TA3 may be positioned to correspond to a portion of the emission area EMA of each sub-pixel SPXn, and the light-blocking area BA may be an area other than the light-transmitting areas TA1, TA2, and TA3.

The upper bank layer UBN may be located on the bank layer BNL to overlap the bank layer BNL. The upper bank layer UBN may be located in a grid pattern including portions extending in the first direction DR1 and the second direction DR2. The upper bank layer UBN may surround the emission area EMA or a portion where the light-emitting elements ED are located, and may distinguish the sub-pixels SPXn including the emission area EMA and the subsidiary area SA together with the above-described bank layer BNL. The upper bank layer UBN may form a space in which the light-transmissive layer LTL is located. The upper bank layer UBN is made hydrophobic to reduce or prevent the likelihood of the ink overflowing into the adjacent sub-pixels SPXn when the ink of the light-transmissive layer LTL is applied.

The light-transmissive layer LTL may be located in a region surrounded by the upper bank layer UBN. The light-transmissive layer LTL may be in direct contact with the first insulating layer PAS1 and the connection electrodes CNE. The light-transmissive layer LTL may be located in the light-transmitting areas TA1, TA2, and TA3 surrounded by the upper bank layer UBN to form an island-shaped pattern in the display area DPA. However, the present disclosure is not limited thereto, and each of the light-transmissive layers LTL may extend in one direction, and may be located over the plurality of sub-pixels SPXn to form a linear pattern.

The light-transmissive layer LTL may be located in each sub-pixel SPXn to correspond to each of the light-transmitting areas TA1, TA2, and TA3. The light-transmissive layer LTL may include a first base resin BRS1, and scatterers SCP included in the first base resin BRS1. The light-transmissive layer LTL transmits the red light of the first color, green light of the second color, and/or the blue light of the third color emitted from the light-emitting element ED while maintaining the respective wavelengths of light. The scatterers SCP of the light-transmissive layer LTL may serve to adjust an emission path of light emitted through the light-transmissive layer LTL.

The scatterers SCP may be metal oxide particles or organic particles. Examples of the metal oxide may include titanium oxide (TiO₂), zirconium oxide (ZrO₂), aluminum oxide (Al₂O₃), indium oxide (In₂O₃), zinc oxide (ZnO), tin oxide (SnO₂), etc. Examples of the material of the organic particles may include an acrylic resin, a urethane resin, etc.

The first to base resin BRS1 may include a transparent organic material. For example, the first base resin BRS1 may include an epoxy resin, an acrylic resin, a cardo resin, an imide resin, or the like.

In some embodiments, the light-transmissive layer LTL may be formed through an inkjet printing process or a photoresist process. The light-transmissive layer LTL may be formed by jetting or applying a material forming the light-transmissive layer LTL in the areas surrounded by the upper bank layer UBN, and then performing drying or exposing and developing processes. As an example, in one or more embodiments in which the light-transmissive layer LTL is formed by the inkjet printing process, in FIG. 14, upper surfaces of respective layers of the light-transmissive layer LTL may be formed to be curved, such that edge portions of the light-transmissive layer LTL adjacent to the upper bank layer UBN may be higher than central portions thereof. However, the present disclosure is not limited thereto. In one or more embodiments in which the light-transmissive layer LTL are formed by the photoresist process, upper surfaces of respective layers of the light-transmissive layer LTL may be formed to be flat, such that an edge portion of the light-transmissive layer LTL adjacent to the upper bank layer UBN may be parallel to an upper surface of the upper bank layer UBN, or such that central portion of the light-transmissive layer LTL may be higher than edge portions thereof, unlike FIG. 6.

The first capping layer CPL1 may be located on the light-transmissive layer LTL and the upper bank layer UBN. The first capping layer CPL1 may reduce or prevent impurities, such as moisture or air from penetrating from the outside to damage or contaminate the light-transmissive layer LTL. The first capping layer CPL1 may include an inorganic insulating material.

The overcoat layer OC may be located over the entire surface of the display area DPA and the non-display area NDA on the first capping layer CPL1. The overcoat layer OC may protect members located on the substrate SUB in addition to the first capping layer CPL1, and may partially compensate for a step difference occurring under the first capping layer CPL1. For example, the overcoat layer OC may compensate for the step formed by the light-transmissive layer LTL, the upper bank layer UBN, and the bank layer BNL under the display area DPA, so that the polarizing plate POL is formed on a flat surface.

The polarizing plate POL may be located on the overcoat layer OC. The polarizing plate POL may reduce reflected external light by absorbing a portion of the light introduced from the outside of the display device 10.

The display device 10 according to one or more embodiments may emit light of different colors from each of the sub-pixels SPXn. For example, the light-emitting element ED of the first sub-pixel SPXn may emit red light of a first color, and the light of the first color may pass through the light-transmissive layer LTL and the polarizing plate POL to the outside. The light-emitting element ED of the second sub-pixel SPXn may emit green light of a second color, and the light of the second color may pass through the light-transmissive layer LTL and the polarizing plate POL to the outside. The light-emitting element ED of the third sub-pixel SPXn may emit blue light of a third color, and the light of the third color may pass through the light-transmissive layer LTL and the polarizing plate POL to the outside.

The display device 10 according to one or more embodiments may include a first insulating layer PAS1 or a second insulating layer PAS2 or a light-blocking layer LSL including a light-blocking material. Accordingly, it is possible to reduce or prevent external light reflected from the electrodes RME and/or wirings, thereby improving display quality.

In concluding the detailed description, those skilled in the art will appreciate that many variations and modifications can be made to the embodiments without substantially departing from the aspects of the present disclosure. Therefore, the disclosed embodiments are used in a generic and descriptive sense only and not for purposes of limitation.

What is claimed is:

1. A display device comprising:
a substrate;
a first electrode and a second electrode above the substrate, extending in one direction, and spaced apart from each other in another direction;
a light-emitting element above the first electrode and the second electrode;
a first connection electrode contacting one end portion of the light-emitting element;
a second connection electrode contacting another end portion of the light-emitting element; and
a first insulating layer between the light-emitting element and the first and second electrodes, and comprising a light-blocking material.

2. The display device of claim 1, wherein the first insulating layer contacts top surfaces of the first electrode and the second electrode, and contacts a bottom surface of the light-emitting element.

3. The display device of claim 1, wherein the light-blocking material comprises a black pigment comprising carbon black.

4. The display device of claim 1, wherein the first insulating layer comprises an organic material with the light-blocking material scattered therein.

5. The display device of claim 1, further comprising a bank layer above the first insulating layer, and separating an emission area from a subsidiary area.

6. The display device of claim 5, wherein the first insulating layer overlaps an entirety of the first electrode and the second electrode in the emission area.

7. The display device of claim 1, further comprising a first bank pattern above the substrate and the first electrode, and a second bank pattern above the substrate and the second electrode,
wherein the first insulating layer overlaps the first bank pattern and the second bank pattern.

8. The display device of claim 1, further comprising a second insulating layer between the light-emitting element and the first insulating layer,
wherein the second insulating layer does not comprise the light-blocking material.

9. The display device of claim 8, wherein the second insulating layer is in contact with a bottom surface of the light-emitting element and a top surface of the first insulating layer.

10. The display device of claim 8, wherein the second insulating layer entirely overlaps the first insulating layer.

11. The display device of claim 1, further comprising:
a light-transmissive layer above the first connection electrode and the second connection electrode, and configured to transmit light emitted from the light-emitting element;
an overcoat layer above the light-transmissive layer; and
a polarizing plate above the overcoat layer.

12. The display device of claim 1, wherein the light-emitting element comprises a first semiconductor layer comprising a p-type dopant, a second semiconductor layer above the first semiconductor layer and comprising an n-type dopant, and an emissive layer between the first insulating layer and the second insulating layer.

13. A display device comprising:
a substrate;
a first electrode and a second electrode above the substrate, extending in one direction, and spaced apart from each other another direction;
a first insulating layer above the first electrode and the second electrode;
light-emitting elements above the first insulating layer, and between the first electrode and the second electrode;
a first connection electrode contacting one end portions of the light-emitting elements, and overlapping the first electrode;
a second connection electrode contacting other end portions of the light-emitting element, and overlapping the second electrode; and
a light-blocking layer above the first insulating layer, the first connection electrode, and the second connection electrode.

14. The display device of claim 13, wherein the light-blocking layer comprises an organic material and a light-blocking material scattered therein.

15. The display device of claim 13, wherein the light-emitting elements do not overlap the first electrode and the second electrode.

16. The display device of claim 15, wherein a gap between the first electrode and the second electrode is greater than a length of the light-emitting elements.

17. The display device of claim 13, further comprising a bank layer between the first insulating layer and the light-blocking layer, and separating an emission area from a subsidiary area.

18. The display device of claim 17, wherein the light-blocking layer defines a first opening exposing one or more of the light-emitting elements in the emission area.

19. The display device of claim 13, wherein the light-blocking layer does not overlap the light-emitting elements.

20. The display device of claim 13, wherein the light-emitting elements emit any one of light of a first color, light of a second color, and light of a third color, and
wherein the first color is red, the second color is green, and the third color is blue.
